(19) United States
(12) Patent Application Publication
(10) Pub. No.: US 2014/0008747 A1
(43) Pub. Date: Jan. 9, 2014

(54) METHOD OF PRODUCING ORGANIC PHOTOELECTRIC CONVERSION DEVICE

(71) Applicant: Yasunori Uetani, Tsukuba-shi (JP)

(72) Inventor: Yasunori Uetani, Tsukuba-shi (JP)

(73) Assignee: SUMITOMO CHEMICAL COMPANY, LIMITED, Chuo-ku, Tokyo (JP)

(21) Appl. No.: 14/004,694

(22) PCT Filed: Mar. 2, 2012
(86) PCT No.: PCT/JP2012/056047

§ 371 Date: Sep. 26, 2013

(30) Foreign Application Priority Data
Mar. 29, 2011 (JP) 2011-071898
Apr. 26, 2011 (JP) 2011-097976
Jul. 5, 2011 (JP) 2011-148861

(51) Int. Cl. H01L 51/42

(52) U.S. Cl. CPC H01L 51/42
USPC 257/431; 438/82

(57) ABSTRACT

An organic photoelectric conversion device can be easily produced by a method of producing an organic photoelectric conversion device, comprising forming an anode, forming an active layer on the anode, then, forming a cathode on the active layer by a coating method.

### TECHNICAL FIELD

The present invention relates to a method of producing an organic photoelectric conversion device.

### BACKGROUND ART

An organic photoelectric conversion device used for organic solar batteries and optical sensors and the like is constituted of a pair of electrodes (anode and cathode) and an active layer disposed between the electrodes, and fabricated by sequentially laminating these electrodes and an active layer and the like in the prescribed order.

An anode and an active layer are formed by a given film formation method such as a vacuum vapor deposition method, a coating method and the like.

For example, there is a known method for producing an organic photoelectric conversion device in which an active layer is formed by coating on a cathode composed a metal film and a solution containing poly(3,4-ethylenedioxythiophene)/poly(4-styrenesulfonic acid) (PEDOT/PSS) is coated on the active layer to form an anode thereon (see, e.g., Thin Solid Films, 2005, No. 491, pp. 298 to 300).

The above-described literature discloses sequential coating and formation of an active layer and an anode on a cathode as one method of producing an organic photoelectric conversion device, however, a different method of producing an organic photoelectric conversion device is sought for improving the degree of freedom of design in forming an organic photoelectric conversion device.

### SUMMARY OF THE INVENTION

The present invention provides a novel method of producing an organic photoelectric conversion device.

The present invention relates to a method of producing an organic photoelectric conversion device, comprising forming an anode, forming an active layer on the above-described anode, then, forming a cathode on the above-described active layer by a coating method.

Further, the present invention relates to the method of producing an organic photoelectric conversion device, in which after formation of the above-described active layer and before formation of the above-described cathode, a coating solution containing an electron transporting material is coated on the active layer to form a functional layer.

Furthermore, the present invention relates to the method of producing an organic photoelectric conversion device, in which the above-described electron transporting material is granulous zinc oxide.

### MODES FOR CARRYING OUT THE INVENTION

The present invention will be illustrated in detail below.

The organic photoelectric conversion device obtained by the production method of the present invention is an organic photoelectric conversion device having a constitution in which an anode, an active layer and a cathode are laminated in this order on a supporting substrate, in which the cathode is formed by a coating method.

The coating method is capable of forming a film without introducing a vacuum atmosphere, differing from a vacuum vapor deposition method. That is, the coating method is believed as one film forming method capable of simplifying a film formation step and reducing production cost.

In general, at least one of an anode and a cathode is constituted of a transparent or semi-transparent electrode. Incident light from a transparent or semi-transparent electrode is absorbed by an electron accepting compound and/or an electron donating compound described later in an active layer, thereby generating an exciton composed of an electron and a hole mutually linked. If this exciton moves in an active layer and reaches a hetero-junction interface wherein an electron accepting compound and an electron donating compound are adjacent, then, an electron and a hole are separated due to a difference in the HOMO energy and the LUMO energy between them, and independently movable charges (electron and hole) are generated. The generated charges move to electrodes and are taken out toward outside as electric energy (current).

The organic photoelectric conversion device is usually formed on a supporting substrate. As the supporting substrate, those showing no chemical change in fabricating the organic photoelectric conversion device are preferably used. The supporting substrate includes, for example, a glass substrate, a plastic substrate, a polymer film and a silicon plate. In the case of an organic photoelectric conversion device of incorporating light from the transparent or opaque anode side, a substrate having high light permeability is suitably used as the supporting substrate. In the case of fabrication of an organic photoelectric conversion device on an opaque substrate, light cannot be incorporated from the anode side, thus, the cathode is constituted of a transparent or semi-transparent electrode. By use of such an electrode, light can be incorporated from the cathode opposite to an anode disposed on the supporting substrate side eve if an opaque supporting substrate is used.

As the anode, an electrically conductive metal oxide film, a metal film, an electrically conductive film containing an organic substance and the like are used. Specifically, use is made of films composed of indium oxide, zinc oxide, tin oxide, indium tin oxide (Indium Tin Oxide: abbreviated as ITO), indium zinc oxide (Indium Zinc Oxide: abbreviated as IZO), gold, platinum, silver, copper, aluminum, polyaniline and derivatives thereof, polythiophene and derivatives thereof, and the like. Of them, films composed of ITO, IZO and tin oxide are preferably used as the anode. In an organic photoelectric conversion device having a constitution of incorporating light from the anode side, for example, a transparent or semi-transparent electrode is used as the anode in which the thickness of the film constituting the anode described above is adjusted so that light permeates the film.

The active layer can take a form composed of a single layer or a form composed of several layers laminated. The single-layered active layer is constituted of a layer containing an electron accepting compound and an electron donating compound.

The active layer having a constitution in which several layers are laminated is, for example, constituted of a laminate obtained by laminating a first active layer containing an electron donating compound and a second active layer containing an electron accepting compound. In this case, the first active layer is disposed closer to the anode than the second active layer.

Also permissible is a constitution in which several active layers are laminated via an intermediate layer. In this case, a multi-junction type device (tandem type device) is obtained. In this case, each active layer may be a single-layered type one containing an electron accepting compound and an electron donating compound or a laminated type one constituted of a laminate obtained by laminating a first active layer containing an electron donating compound and a second active layer containing an electron accepting compound.

It is preferable that the active layer is formed by a coating method. It is preferable that the active layer contains a high molecular weight compound, and one high molecular weight compound may be contained singly or two or more high molecular weight compounds may be contained in combination. For enhancing the charge transportability of the active layer, an electron donating compound and/or an electron accepting compound may be mixed in the above-described active layer.

The electron accepting compound used in an organic photoelectric conversion device is composed of a compound having its HOMO energy higher than the HOMO energy of an electron donating compound and having its LUMO energy higher than the LUMO energy of an electron donating compound.

The electron donating compound may be a low molecular weight compound or a high molecular weight compound. The low molecular weight electron donating compound includes, for example, phthalocyanine, metallophthalocyanine, porphyrin, metalloporphyrin, oligothiophene, tetracene, pentacene and rubrene.

The high molecular weight electron donating compound includes, for example, polyvinyl carbazole and derivatives thereof, polysilane and derivatives thereof, polyisloxane derivatives having an aromatic amine in the side chain or the main chain, polyaniline and derivatives thereof, polythiophene and derivatives thereof, polypyrrole and derivatives thereof, polyphenylenevinylene and derivatives thereof, polythienylenevinylene and derivatives thereof and polyfluorene and derivatives thereof.

The electron accepting compound may be a low molecular weight compound or a high molecular weight compound. The low molecular weight electron accepting compound includes, for example, oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, and phenanthrene derivatives such as bathocuproin and the like. The high molecular weight electron accepting compound includes, for example, polyvinyl carbazole and derivatives thereof, polysilane and derivatives thereof, polyisloxane derivatives having an aromatic amine in the side chain or the main chain, polyaniline and derivatives thereof, polythiophene and derivatives thereof, polypyrrole and derivatives thereof, polyphenylenevinylene and derivatives thereof, polythienylenevinylene and derivatives thereof, and polyfluorene and derivatives thereof. Of them, especially fullerenes and derivatives thereof are preferable.

The fullerenes include C₆₀, C₇₀, carbon nano tubes, and derivatives thereof. Specific structures of C₆₀ fullerene derivatives include the following structures.

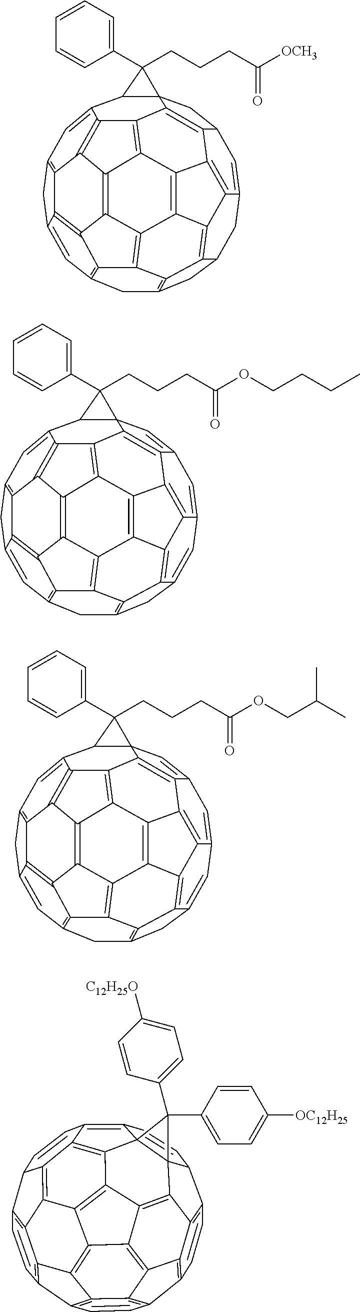

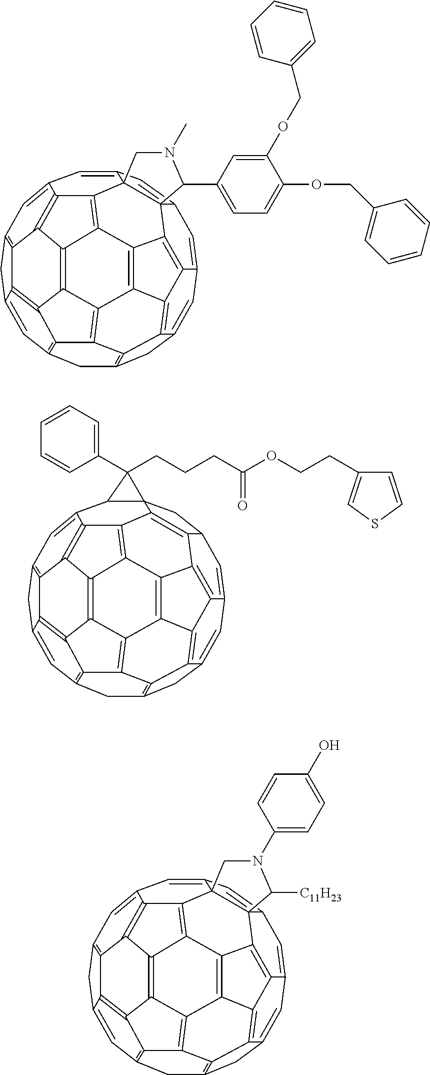

In a constitution in which the active layer contains an electron accepting compound composed of fullerenes and/or derivatives of fullerenes, and an electron donating compound, the proportion of fullerenes and derivatives of fullerenes is preferably 10 to 1000 parts by weight, more preferably 50 to 500 parts by weight with respect to 100 parts by weight of an electron donating compound. It is preferable for an organic photoelectric conversion device to have an active layer having the above-described single-layered constitution, and it is more preferable for an organic photoelectric conversion device to have an active layer having a single-layered constitution containing an electron accepting compound composed of fullerenes and/or derivatives of fullerenes, and an electron donating compound, since the quantity of hetero-junction interfaces contained is larger in this case.

Especially, the active layer preferably contains a conjugated high molecular weight compound, and fullerenes and/or derivatives of fullerenes. The conjugated high molecular weight compound used in the active layer includes, for example, polythiophene and derivatives thereof, polyphenylenevinylene and derivatives thereof, and polyfluorene and derivatives thereof.

The thickness of the active layer is usually 1 nm to 100 μm, preferably 2 nm to 1000 nm, more preferably 5 nm to 500 nm, further preferably 20 nm to 200 nm.

The organic photoelectric conversion device has not only an active layer but also a prescribed functional layer between electrodes in some cases. Regarding such a functional layer, it is preferable that a functional layer containing an electron transporting material is disposed between an active layer and a cathode.

The functional layer is preferably formed by a coating method, and it is preferable that, for example, the functional layer is formed by coating a coating solution containing an electron transporting material and a solvent on the surface of a layer on which the functional layer is to be provided. In the present invention, the coating solution includes also dispersions such as an emulsion, a suspension and the like.

The electron transporting material includes, for example, zinc oxide, titanium oxide, zirconium oxide, tin oxide, indium oxide, ITO (indium tin oxide), FTO (fluorine-doped tin oxide), GZO (gallium-doped zinc oxide), ATO (antimony-doped tin oxide) and AZO (aluminum-doped zinc oxide), and of them, zinc oxide is preferable. In forming a functional layer, it is preferable that the functional layer is formed by coating a coating solution containing granulous zinc oxide. For such an electron transporting material, so-called zinc oxide nano particles are preferably used, and it is more preferable that a functional layer is formed by using an electron transporting material composed only of zinc oxide nano particles. The sphere equivalent average particle size of zinc oxide is preferably 1 nm to 1000 nm, more preferably 10 nm to 100 nm. The average particle size is measured by a laser light scattering method and an X-ray diffraction method.

When a functional layer containing an electron transporting material is provided between a cathode and an active layer, peeling of the cathode can be prevented and simultaneously, the efficiency of electro injection from the active layer into the cathode can be enhanced. It is preferable that a functional layer is disposed adjacent to an active layer, and it is further preferable that it is disposed also adjacent to a cathode. By providing a functional layer containing an electron transporting material as described above, peeling of the cathode can be prevented and simultaneously, the efficiency of electro injection from the active layer into the cathode can be further enhanced. By providing such a functional layer, an organic photoelectric conversion device having high reliability and showing high photoelectric conversion efficiency can be realized.

The functional layer containing an electron transporting material functions as a so-called electron transporting layer and/or electron injection layer. By providing such a functional layer, the efficiency of injection of electrons into a cathode can be enhanced, injection of holes from an active layer can be prevented, an electron transporting ability can be enhanced, an active layer can be protected from erosion by a coating solution used in forming a cathode by a coating method, and degradation of an active layer can be suppressed.

It is preferable that the functional layer containing an electron transporting material is constituted of a material manifesting high wettability to a coating solution used in forming a cathode by a coating method. Specifically, it is preferable that the functional layer containing an electron transporting material manifests higher wettability to the coating solution used in forming a cathode by a coating method than the wettability of an active layer to the coating solution. By forming a cathode on such a functional layer by a coating method, the coating solution successfully wets and spreads on the surface of the functional layer in forming the cathode, and the cathode having uniform thickness can be formed.

It is preferable that the coating solution containing an electron transporting material contains at least one selected from the group consisting of complexes, salts and hydroxides of alkali metals and complexes, salts and hydroxides of alkaline earth metals (hereinafter, referred to as “complex, salt or hydroxide of alkali metal or alkaline earth metal” in some cases). By using such a coating solution, a functional layer containing a complex, salt or hydroxide of an alkali metal or alkaline earth metal can be formed. By inclusion of a complex, salt or hydroxide of an alkali metal or alkaline earth metal, electron injection efficiency can be further enhanced.

It is preferable that the complex, salt or hydroxide of an alkali metal or alkaline earth metal is soluble in the solvent of the above-described coating solution. The alkali metal includes lithium, sodium, potassium, rubidium and cesium. The alkaline earth metal includes magnesium, calcium, strontium and barium. The complex includes β-diketone complexes, and the salt includes alkoxides, phenoxides, carboxylates and carbonates.

Specific examples of the complex, salt or hydroxide of an alkali metal or alkaline earth metal include sodium acetylacetonate, cesium acetylacetonate, calcium bisacetylacetonate, barium bisacetylacetonate, sodium methoxide, sodium phenoxide, sodium tert-butoxide, sodium tert-pentoxide, sodium acetate, sodium citrate, cesium carbonate, cesium acetate, sodium hydroxide and cesium hydroxide.

Of them, sodium acetylacetonate, cesium acetylacetonate and cesium acetate are preferable.

In the coating solution containing an electron transporting material, if the amount of the granulous electron transporting material is defined as 100 parts by weight, then, the total weight of the complex, salt or hydroxide of an alkali metal or alkaline earth metal is 1 to 1000, preferably 5 to 500 parts by weight.

The cathode can take a form composed of a single layer or a form composed of several layers laminated. In the present embodiment, the cathode is formed by a coating method. The coating solution used in forming the cathode by a coating method contains constituent materials of the cathode, and a solvent. The cathode preferably contains a high molecular weight compound showing electric conductivity, and it is preferable that the cathode is substantially composed of a high molecular weight compound showing electric conductivity. The cathode constituent materials include organic materials such as polyaniline and derivatives thereof, polythiophene and derivatives thereof, polypyrrole and derivatives thereof and the like.

The cathode preferably contains polythiophene and/or polythiophene derivative, and it is preferable that the cathode is substantially composed of polythiophene and/or polythiophene derivative. The cathode preferably contains polyaniline and/or polyaniline derivative, and it is preferable that the cathode is composed of polyaniline and/or polyaniline derivative.

Specific examples of polythiophene and derivatives thereof include compounds containing as a repeating unit at least one among a plurality of structural formulae shown below.

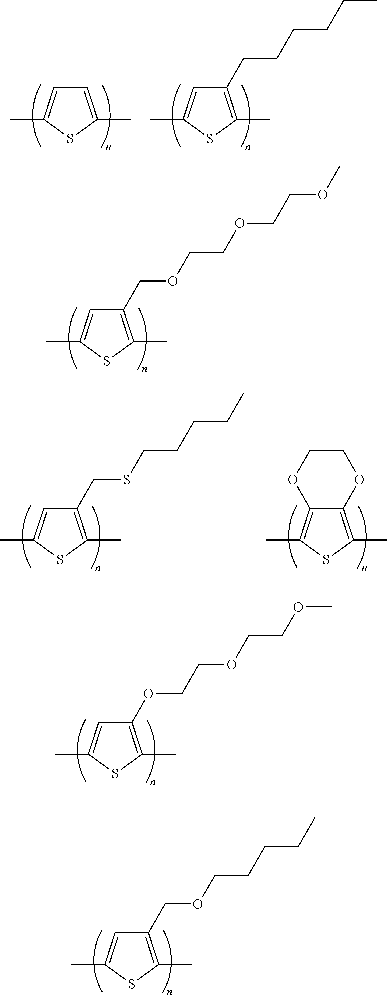

(wherein, n represents an integer of 1 or more.)

Specific examples of polypyrrole and derivatives thereof include compounds containing as a repeating unit at least one among a plurality of structural formulae shown below.

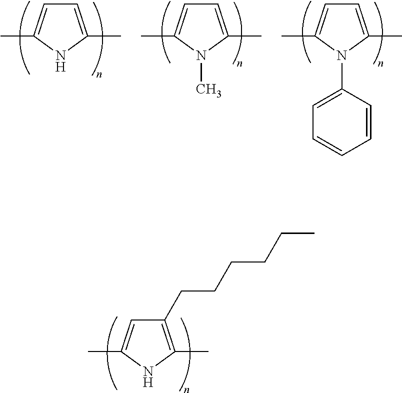

(wherein, n represents an integer of 1 or more.)

Specific examples of polyaniline and derivatives thereof include compounds containing as a repeating unit at least one among a plurality of structural formulae shown below.

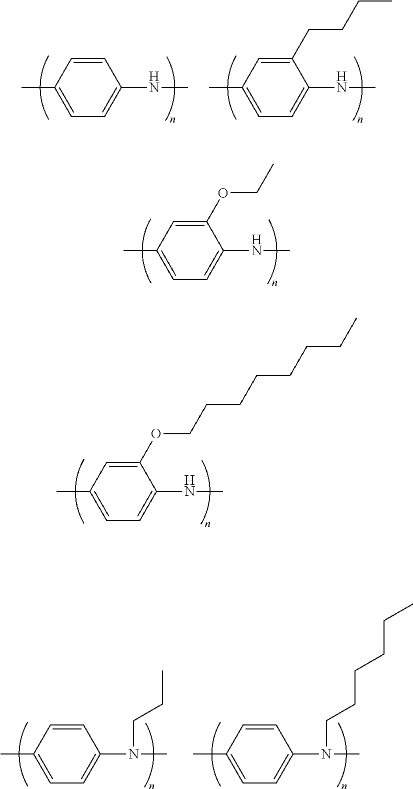

(wherein, n represents an integer of 1 or more.)

Among the above-described cathode constituent materials, PEDOT/PSS composed of poly(3,4-ethylenedioxythiophene) (PEDOT) and poly(4-styrenesulfonic acid) (PSS) is preferably used as a cathode constituent material owing to high photoelectric conversion efficiency.

The cathode may be formed by a coating method using an emulsion or a suspension containing nano particles of an electrically conductive substance, nano wires of an electrically conductive substance or nano tubes of an electrically conductive substance, a dispersion such as a metal paste and the like, a low melting point metal under melted condition, and the like, without limiting to the coating solution containing the above-described organic materials. The electrically conductive substance includes metals such as gold, silver and the like, oxides such as ITO (indium tin oxide) and the like, carbon nano tubes and the like. The cathode may be constituted only of nano particles or nano fibers of an electrically conductive substance, and the cathode may also have a constitution in which nano particles or nano fibers of an electrically conductive substance are dispersed in a prescribed medium such as an electrically conductive polymer and the like, as shown in Japanese Patent Application National Publication No. 2010-525526.

Regarding the constitution of an organic photoelectric conversion device, an additional layer may be further provided between an anode and a cathode, without limiting to the above-described device constitution. The additional layer includes, for example, a hole transporting layer which transports holes, an electron transporting layer which transports electrons, a buffer layer and the like. For example, a hole transporting layer is disposed between an anode and an active layer, an electron transporting layer is disposed between an active layer and a functional layer, and a buffer layer is disposed for example between a cathode and a functional layer, and the like. By providing a buffer layer, surface flatness and charge injection can be promoted.

As the material used in a hole transporting layer or an electron transporting material as the above-described additional layer, electron donating compounds and electron accepting compounds described above can be used. As the material used in a buffer layer as the additional layer, halides, oxides and the like of alkali metals and alkaline earth metals such as lithium fluoride can be used. It is also possible to form a charge transporting layer using fine particles of an inorganic semiconductor such as titanium oxide and the like. For example, an electron transporting layer can be formed by coating a titania solution by a coating method on a ground layer on which the electron transporting layer is to be formed, and further drying the coated solution.

In the method of producing an organic photoelectric conversion device of the present invention, an anode is formed, an active layer is formed on the anode, and a cathode is formed on an active layer by a coating method.

The anode is formed, for example, by forming a film of the above-described anode material on a supporting substrate by a vacuum vapor deposition method, a sputtering method, an ion plating method, a plating method and the like. Further, the anode may be formed by a coating method using a coating solution containing an organic material such as polyaniline and derivatives thereof, polythiophene and derivatives thereof and the like, a metal ink, a metal paste, a low melting point metal in melted condition, and the like.

Though the method of forming an active layer is not particularly restricted, it is preferable to form an active layer by a coating method for simplifying the production step. The active layer can be formed, for example, by a coating method using a coating solution containing the above-described active layer constituent material and a solvent, and for example, can be formed by a coating method using a coating solution containing a conjugated high molecular weight compound and fullerenes and/or derivatives of fullerenes, and a solvent.

The solvent includes, for example, hydrocarbon solvents such as toluene, xylene, mesitylene, tetralin, decalin, bicyclohexyl, butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like, and a mixed solvent composed of two or more of these solvents.

The method of coating a coating solution containing the active layer constituent material includes coating methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet printing method, a dispenser printing method, a nozzle coat method, a capillary coat method and the like, and of them, a spin coat method, a flexo printing method, an inkjet printing method and a dispenser printing method are preferable.

As described above, it is preferable to form a functional layer containing an electron transporting material between an active layer and a cathode. That is, it is preferable that a functional layer is formed by coating a coating solution containing the electron transporting material described above on the active layer, after formation of the active layer and before formation of the cathode.

When a functional layer containing an electron transporting material is disposed adjacent to an active layer, a functional layer is formed by coating the above-described coating solution on the surface of the active layer. In forming a functional layer, it is preferable to use a coating solution causing little damage on a layer (active layer and the like) on which the coating solution is to be coated, and specifically, it is preferable to use a coating solution poorly dissolving a layer (active layer and the like) on which the coating solution is to be coated. For example, it is preferable to form a functional layer using a coating solution causing smaller damage on an active layer than the damage on the active layer caused when a coating solution used in forming a cathode is coated on the active layer, and specifically, it is preferable to form a functional layer using a coating solution more poorly dissolving an active layer than the coating solution used in forming a cathode.

The coating solution used in forming a functional layer by a coating method contains a solvent and the above-described electron transporting material. The solvent of the above-described coating solution includes water, alcohols, ketones and the like, and specific examples of the alcohol include methanol, ethanol, 2-propanol, butanol, ethylene glycol, propylene glycol, butoxyethanol and methoxybutanol and a mixture composed of two or more of these compounds, and specific examples of the ketone include acetone, methyl ethyl ketone, methyl isobutyl ketone, 2-heptanone and cyclohexanone and a mixture composed of two or more of these compounds.

The cathode is formed by a coating method on the surface of an active layer, a functional layer and the like. Specifically, a cathode is formed by coating a coating solution containing a solvent and the above-described cathode constituent material on the surface of an active layer, a functional layer or the like. The solvent of the coating solution used in forming a cathode includes, for example, hydrocarbon solvents such as toluene, xylene, mesitylene, tetralin, decalin, bicyclohexyl, butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like, water, alcohols and a mixed solvent composed of two or more of these solvents. Specific examples of the alcohol include methanol, ethanol, 2-propanol, butanol, ethylene glycol, propylene glycol, butoxyethanol and methoxybutanol.

In the case of forming a cathode using a coating solution causing damage on an active layer and a functional layer, it may be permissible that, for example, the cathode has a two-layer constitution and a film of the first layer is formed using a coating solution not causing damage on an active layer and a functional layer, then, a film of the second layer is formed using a coating solution possibly causing damage on an active layer and a functional layer. By adopting a cathode having such a two-layer constitution, damage on an active layer and a functional layer can be suppressed since the film of the first layer functions as a protective layer even if the film of the second layer is formed using a coating solution possibly causing damage on an active layer and a functional layer. For example, since a functional layer composed of zinc oxide is easily damaged by an acidic solution, it may be permissible that a film of the first layer is formed using a neutral coating solution, and then, a film of the second layer is formed using an acidic solution, thereby forming a cathode having a two-layer constitution, when a cathode is formed on a functional layer composed of zinc oxide.

In the organic photoelectric conversion device of the present invention, a transparent or semi-transparent electrode is irradiated with light such as solar ray and the like to generate photoelectromotive force between electrodes, thus, the organic photoelectric conversion device can be operated as an organic film solar battery. A plurality of organic film solar batteries can also be accumulated and used as an organic film solar battery module.

In the organic photoelectric conversion device of the present invention, a transparent or semi-transparent electrode is irradiated with light under application of voltage between electrodes to cause flow of photocurrent, thus, the organic photoelectric conversion device can be operated as an organic optical sensor. A plurality of organic optical sensors can also be accumulated and used as an organic image sensor.

### EXAMPLES

Examples are shown below for illustrating the present invention further in detail, but the present invention is not limited to them.

In the following examples, the polystyrene-equivalent number-average molecular weight was measured using GPC (PL-GPC2000) manufactured by GPC Laboratory Co., Ltd, as the molecular weight of a polymer. The polymer was dissolved in o-dichlorobenzene so that the concentration of the polymer was about 1% by weight. As the mobile phase of GPC, o-dichlorobenzene was used and allowed to flow at a flow rate of 1 mL/min at a measurement temperature of 140° C. As the column, three columns of PLGEL 10 μm MIXED-B (manufactured by PL Laboratory) were serially connected.

### Synthesis Example 1

### Synthesis of Polymer 1

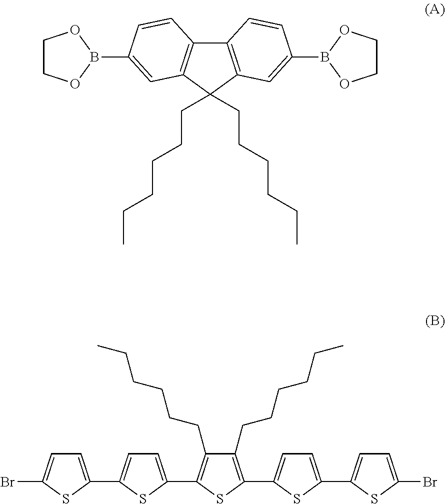 [SMILES: CCCCCCC1(CCCCCC)c2cc(B3OCCO3)ccc2-c2ccc(B3OCCO3)cc21 ; CCCCCCc1c(-c2ccc(-c3ccc(Br)s3)s2)sc(-c2ccc(-c3ccc(Br)s3)s2)c1CCCCCC]

Into a 2 L four-necked flask having an argon-purged internal atmosphere were charged the above-described compound A (7.928 g, 16.72 mmol), the above-described compound B (13.00 g, 17.60 mmol), methyltrioctyl ammonium chloride (trade name: aliquat336, manufactured by Aldrich, CH₃N[(CH₂)₇CH₃]₃Cl, density 0.884 g/mL, 25° C., trademark of Henkel Corporation) (4.979 g) and 405 mL of toluene, and the mixture in the system was bubbled with argon for 30 minutes while stirring.

Dichlorobis(triphenylphosphine)palladium(II) (0.02 g) was added, the mixture was heated up to 105° C., and 42.2 mL of a 2 mol/L sodium carbonate aqueous solution was dropped while stirring. After completion of dropping, these were reacted for 5 hours, and phenylboronic acid (2.6 g) and 1.8 mL of toluene were added and the mixture was stirred at 105° C. for 16 hours. Toluene (700 mL) and a 7.5% sodium diethyldithiocarbamate tri-hydrate aqueous solution (200 mL) were added and the mixture was stirred at 85° C. for 3 hours. The aqueous layer was removed, then, the organic layer was washed with 300 mL of 60° C. ion exchanged water twice, with 300 mL of 60° C. 3% acetic acid once, further with 300 mL of 60° C. ion exchanged water three times. The organic layer was allowed to pass through a column filled with celite, alumina and silica, and the column was washed with 800 mL of hot toluene. The solution was concentrated to 700 mL, then, poured into 2 L of methanol, and the precipitated polymer was isolated by filtration and washed with 500 mL of methanol, acetone and methanol. This was vacuum-dried overnight at 50° C., to obtain 12.21 g of a pentathienyl-fluorene copolymer having a repeating unit represented by the following formula:

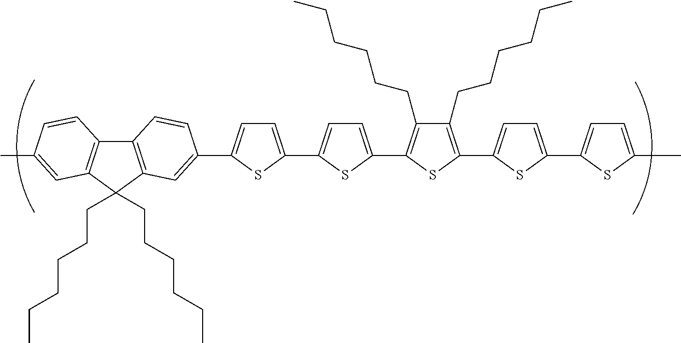

(hereinafter, referred to as “polymer 1”). The polymer 1 had a polystyrene-equivalent number-average molecular weight of 5.4×10⁴ and a polystyrene-equivalent weight-average molecular weight of 1.1×10⁵.

### Synthesis Example 2

### Synthesis of Polymer 2

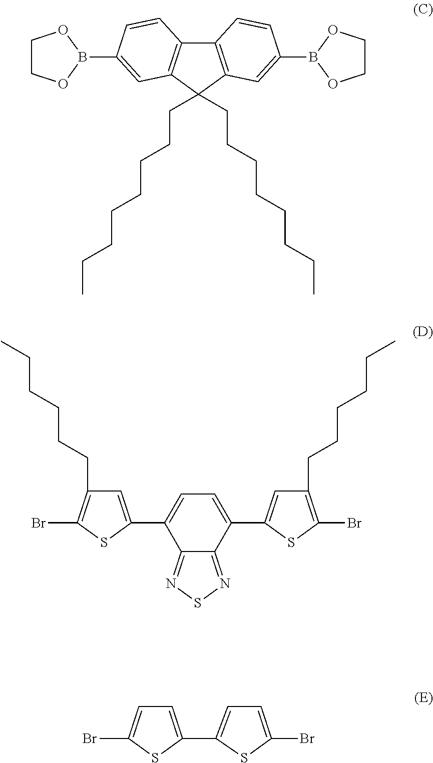 [SMILES: CCCCCCCCC1(CCCCCCCC)c2cc(B3OCCO3)ccc2-c2ccc(B3OCCO3)cc21 ; CCCCCCc1cc(-c2ccc(-c3cc(CCCCCC)c(Br)s3)c3nsnc23)sc1Br ; Brc1ccc(-c2ccc(Br)s2)s1]

Into a 200 mL separable flask were charged 0.65 g of methyltrioctyl ammonium chloride (trade name: aliquat336 (registered trademark), manufactured by Aldrich, CH₃N[(CH₂)₇CH₃]₃Cl, density 0.884 g/mL, 25° C.), 1.5779 g of a compound (C) and 1.1454 g of a compound (E), and a gas in the flask was purged with nitrogen. Into the flask was added 35 mL of argon-bubbled toluene, and the mixture was dissolved by stirring, then, further bubbled with argon for 40 minutes. The temperature of a bath for heating the flask was raised up to 85° C., then, to the reaction solution were added 1.6 mg of palladium acetate and 6.7 mg of tris o-methoxyphenylphosphine, subsequently, 9.5 mL of a 17.5% by weight sodium carbonate aqueous solution was dropped over a period of 6 minutes, while raising the temperature of the bath up to 105° C. After dropping, the mixture was stirred for 1.7 hours while keeping the temperature of the bath at 105° C., thereafter, the reaction solution was cooled down to room temperature.

Next, to the reaction solution were added 1.0877 g of a compound (C) and 0.9399 g of a compound (D), and further, 15 mL of argon-bubbled toluene was added, and the mixture was dissolved by stirring, then, further bubbled with argon for 30 minutes. To the reaction solution were added 1.3 mg of palladium acetate and 4.7 mg of tris o-methoxyphenylphosphine, subsequently, 6.8 mL of a 17.5% by weight sodium carbonate aqueous solution was dropped over a period of 5 minutes while raising the temperature of the bath up to 105° C. After dropping, the mixture was stirred for 3 hours while keeping the temperature of the bath at 105° C. After stirring, to the reaction solution were added 50 mL of argon-bubbled toluene, 2.3 mg of palladium acetate, 8.8 mg of tris o-methoxyphenylphosphine and 0.305 g of phenylboric acid, and the mixture was stirred for 8 hours while keeping the temperature of the bath at 105° C. Next, the aqueous layer of the reaction solution was removed, then, to the organic layer was added an aqueous solution prepared by dissolving 3.1 g of sodium N,N-diethyldithiocarbamate in 30 mL of water, and the mixture was stirred for 2 hours while keeping the temperature of the bath at 85° C. Subsequently, to the reaction solution was added 250 mL of toluene and the reaction solution was separated, and the organic layer was washed with 65 mL of water twice, with 65 mL of 3% by weight acetic acid water twice and with 65 mL of water twice. To the organic layer after washing was added 150 mL of toluene for dilution, and the solution was dropped into 2500 mL of methanol, to cause re-precipitation of a high molecular weight compound. The high molecular weight compound was filtrated, dried under reduced pressure, then, dissolved in 500 mL of toluene. The resultant toluene solution was allowed to pass through a silica gel-alumina column, and the resultant toluene solution was dropped into 3000 mL of methanol, and the precipitated high molecular weight compound was filtrated and dried under reduced pressure before obtaining 3.00 g of a polymer 2. The resultant polymer 2 had a polystyrene-equivalent weight-average molecular weight of 257000 and a polystyrene-equivalent number-average molecular weight of 87000.

The polymer 2 is a block copolymer represented by the following formula.

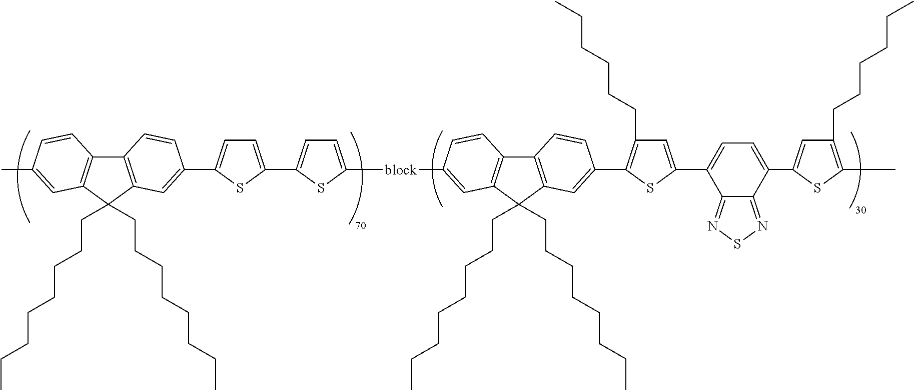

### Synthesis Example 3

### Synthesis of compound 1

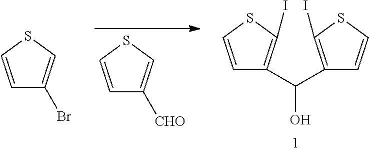

Into a 1000 mL four-necked flask having an argon-purged internal atmosphere were charged 13.0 g (80.0 mmol) of 3-bromothiophene and 80 mL of diethyl ether, to prepare a uniform solution. While keeping the solution at −78° C., 31 mL (80.6 mmol) of a 2.6 M butyllithium (n-BuLi) hexane solution was dropped. After reacting at −78° C. for 2 hours, a solution prepared by dissolving 8.96 g of 3-thiophenealdehyde (80.0 mmol) in 20 mL of diethyl ether was dropped into the reaction solution. After dropping, the reaction solution was stirred at −78° C. for 30 minutes, further, stirred at room temperature (25° C.) for 30 minutes. The reaction solution was cooled down to −78° C. again, and 62 mL (161 mmol) of a 2.6 M n-BuLi hexane solution was dropped over a period of 15 minutes. After dropping, the reaction solution was stirred at −25° C. for 2 hours, further, stirred at room temperature (25° C.) for 1 hour. Thereafter, the reaction solution was cooled to −25° C., and a solution prepared by dissolving 60 g of iodine (236 mmol) in 1000 mL of diethyl ether was dropped over a period of 30 minutes. After dropping, the reaction solution was stirred at room temperature (25° C.) for 2 hours, and 50 mL of a 1 N sodium thiosulfate aqueous solution was added to stop the reaction. To the reaction solution was added diethyl ether, and the organic layer extracted the reaction product was dried over magnesium sulfate, and concentrated to obtain 35 g of a coarse product. The coarse product was purified by re-crystallizing from chloroform, to obtain 28 g of a compound 1.

### Synthesis Example 4

### Synthesis of Compound 2

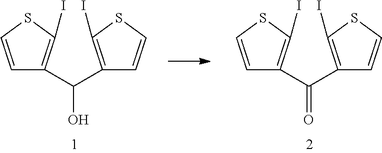 [SMILES: OC(c1ccsc1I)c1ccsc1I ; O=C(c1ccsc1I)c1ccsc1I]

Into a 300 mL four-necked flask were added 10 g (22.3 mmol) of bis(iodothienyl)methanol (compound 1) and 150 mL of methylene chloride, to prepare a uniform solution. To the solution was added 7.50 g (34.8 mmol) of pyridinium chlorochromate, and the mixture was stirred at room temperature (25° C.) for 10 hours. The reaction solution was filtrated to remove insoluble materials, then, the filtrate was concentrated, to obtain 10.0 g (22.4 mmol) of a compound 2.

### Synthesis Example 5

### Synthesis of Compound 3

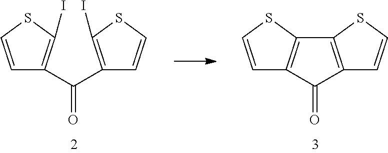 [SMILES: O=C(c1ccsc1I)c1ccsc1I ; O=C1c2ccsc2-c2sccc21]

Into a 300 mL flask having an argon-purged internal atmosphere were added 10.0 g (22.3 mmol) of a compound 2, 6.0 g (94.5 mmol) of a copper powder and 120 mL of dehydrated N,N-dimethylformamide (hereinafter, referred to as DMF in some cases), and the mixture was stirred at 120° C. for 4 hours. After the reaction, the flask was cooled down to room temperature (25° C.), and the reaction solution was allowed to pass through a silica gel column, to remove insoluble components. Thereafter, to the reaction solution was added 500 mL of water, and further, chloroform was added, and the organic layer containing the reaction product was extracted. The organic layer as a chloroform solution was dried over magnesium sulfate, and concentrated to obtain a coarse product. The coarse product was purified by a silica gel column using chloroform as the developing liquid, to obtain 3.26 g of a compound 3.

### Synthesis Example 6

### Synthesis of Compound 4

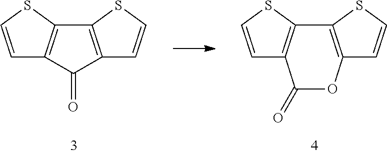 [SMILES: O=C1c2ccsc2-c2sccc21 ; O=c1oc2ccsc2c2sccc12]

Into a 300 mL four-necked flask equipped with a mechanical stirrer and having an argon-purged internal atmosphere were added 3.85 g (20.0 mmol) of a compound 3, 50 mL of chloroform and 50 mL of trifluoroacetic acid, to prepare a uniform solution. To the solution was added 5.99 g (60 mmol) of sodium perborate mono-hydrate, and the mixture was stirred at room temperature (25° C.) for 45 minutes. Thereafter, to the reaction solution was added 200 mL of water, and further, chloroform was added, and the organic layer containing the reaction product was extracted. The organic layer as a chloroform solution was allowed to pass through a silica gel column, and the solvent of the filtrate was distilled off by an evaporator. The residue was re-crystallized from methanol, to obtain 534 mg of a compound 4.

¹H NMR in CDCl₃ (ppm): 7.64 (d, 1H), 7.43 (d, 1H), 7.27 (d, 1H), 7.10 (d, 1H)

### Synthesis Example 7

### Synthesis of Compound 5

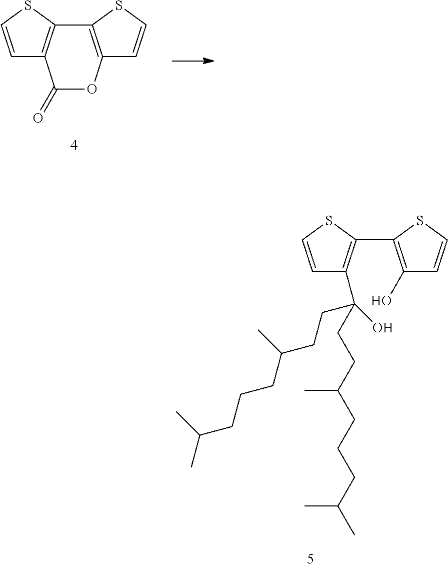 [SMILES: O=c1oc2ccsc2c2sccc12 ; CC(C)CCCC(C)CCC(O)(CCC(C)CCCC(C)C)c1ccsc1-c1sccc1O]

Into a 100 mL four-necked flask having an argon-purged internal atmosphere were added 1.00 g (4.80 mmol) of a compound 4 and 30 mL of dehydrated THF, to prepare a uniform solution. While keeping the flask at −20° C., to the reaction solution was added 12.7 mL of a 1 M 3,7-dimethyloctylmagnesium bromide ether solution. Thereafter, the temperature was raised up to −5° C. over a period of 30 minutes, and at the same temperature, the reaction solution was stirred for 30 minutes. Thereafter, the temperature was raised up to 0° C. over a period of 10 minutes, and at the same temperature, the reaction solution was stirred for 1.5 hours. Thereafter, to the reaction solution was added water to stop the reaction, and further, ethyl acetate was added, and the organic layer extracted the reaction product was dried over sodium sulfate, allowed to pass through a silica gel column, then, the solvent was distilled off to obtain 1.50 g of a compound 5.

¹H NMR in CDCl₃ (ppm): 8.42 (b, 1H), 7.25 (d, 1H), 7.20 (d, 1H), 6.99 (d, 1H), 6.76 (d, 1H), 2.73 (b, 1H), 1.90 (m, 4H), 1.58-1.02 (b, 20H), 0.92 (s, 6H), 0.88 (s, 12H)

### Synthesis Example 8

### Synthesis of Compound 6

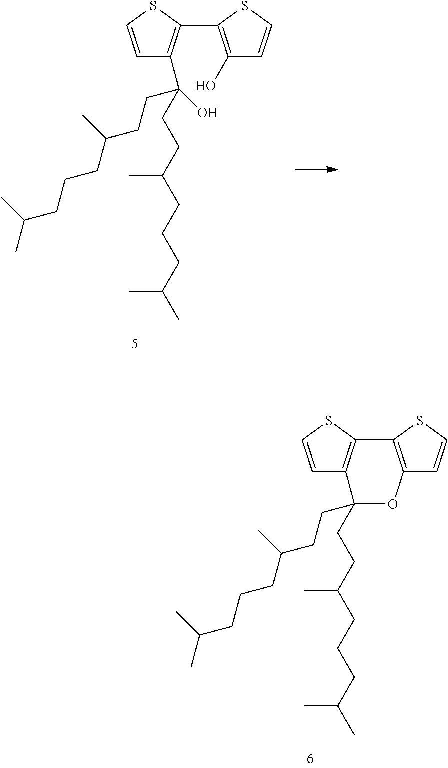 [SMILES: CC(C)CCCC(C)CCC(O)(CCC(C)CCCC(C)C)c1ccsc1-c1sccc1O ; CC(C)CCCC(C)CCC1(CCC(C)CCCC(C)C)Oc2ccsc2-c2sccc21]

Into a 200 mL flask having an argon-purged internal atmosphere were added 1.50 g of a compound 5 and 30 mL of toluene, to prepare a uniform solution. Into the solution was charged 100 mg of sodium p-toluenesulfonate mono-hydrate, and the mixture was stirred at 100° C. for 1.5 hours. The reaction solution was cooled down to room temperature (25° C.), then, 50 mL of water was added, and further, toluene was added, and the organic layer containing the reaction product was extracted. The organic layer as a toluene solution was dried over sodium sulfate, and the solvent was distilled off. The resultant coarse product was purified by a silica gel column using hexane as the developing solvent, to obtain 1.33 g of a compound 6.

The procedures up to here were repeated several times.

¹H NMR in CDCl₃ (ppm): 6.98 (d, 1H), 6.93 (d, 1H), 6.68 (d, 1H), 6.59 (d, 1H), 1.89 (m, 4H), 1.58-1.00 (b, 20H), 0.87 (s, 6H), 0.86 (s, 12H)

### Synthesis Example 9

### Synthesis of Compound 7

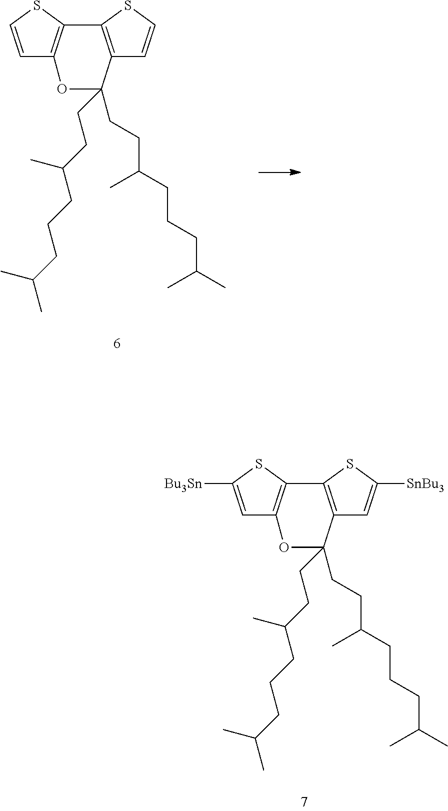

Into a 200 mL flask having an argon-purged internal atmosphere were charged 2.16 g (4.55 mmol) of a compound 6 and 100 mL of dehydrated THF, to prepare a uniform solution. While keeping the solution at −78° C., 4.37 mL (11.4 mmol) of a 2.6 M n-BuLi hexane solution was dropped into the solution over a period of 10 minutes. After dropping, the reaction solution was stirred at −78° C. for 30 minutes, then, stirred at room temperature (25° C.) for 2 hours. Thereafter, the flask was cooled down to −78° C., and to the reaction solution was added 4.07 g (12.5 mmol) of tributyltin chloride. After addition, the reaction solution was stirred at −78° C. for 30 minutes, then, stirred at room temperature (25° C.) for 3 hours. Thereafter, to the reaction solution was added 200 mL of water to stop the reaction, and ethyl acetate was added, and the organic layer extracted the reaction product was dried over sodium sulfate, and the solvent was distilled off by an evaporator. The resultant oily substance was purified by a silica gel column using hexane as the developing solvent. As the silica gel in the silica gel column, silica gel which had previously been immersed in hexane containing 5 wt % triethylamine for 5 minutes, then, rinsed with hexane was used. Purification thereof was performed, to obtain 3.52 g (3.34 mmol) of a compound 7.

### Synthesis Example 10

### Synthesis of Compound 9

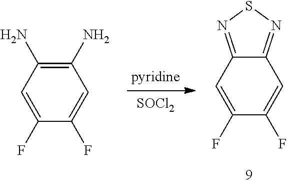

Into a 500 mL flask were charged 10.2 g (70.8 mmol) of 4,5-difluoro-1,2-diaminobenzene (manufactured by Tokyo Chemical Industry Co., Ltd.) and 150 mL of pyridine, to prepare a uniform solution. While keeping the flask at 0° C., 16.0 g (134 mmol) of thionyl chloride was dropped into the flask. After dropping, the flask was warmed at 25° C., and the mixture was reacted for 6 hours. Thereafter, 250 mL of water was added, and the reaction product was extracted with chloroform. The organic layer as a chloroform solution was dried over sodium sulfate, and concentrated to obtain a precipitated solid which was then purified by re-crystallization. As the solvent for re-crystallization, methanol was used. After purification, 10.5 g (61.0 mmol) of a compound 9 was obtained.

### Synthesis Example 11

### Synthesis of Compound 10

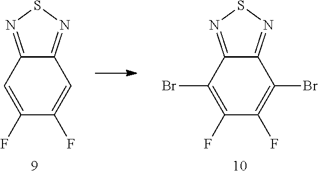 [SMILES: Fc1cc2nsnc2cc1F ; Fc1c(F)c(Br)c2nsnc2c1Br]

Into a 100 mL flask were charged 2.00 g (11.6 mmol) of a compound 9 and 0.20 g (3.58 mmol) of an iron powder, and the flask was heated at 90° C. Into this flask, 31 g (194 mmol) of bromine was dropped over a period of 1 hour. After dropping, the mixture was stirred at 90° C. for 38 hours. Thereafter, the flask was cooled down to room temperature (25° C.), and 100 mL chloroform was added for dilution. The resultant solution was poured into 300 mL of a 5 wt % sodium sulfite aqueous solution, and the mixture was stirred for 1 hour. The organic layer of the resultant mixed solution was separated by separatory funnel, and the aqueous layer was extracted with chloroform three times. The resultant extraction liquid was combined with the previously separated organic layer, and dried over sodium sulfate, and the solvent was distilled off by an evaporator. The resultant yellow solid was dissolved in 90 mL methanol heated at 55° C., thereafter, the solution was cooled down to 25° C. The precipitated crystal was filtrated, thereafter, dried under reduced pressure at room temperature (25° C.), to obtain 1.50 g of a compound 10.

¹⁹F NMR (CDCl₃, ppm): −118.9 (s, 2F)

### Synthesis Example 12

### Synthesis of Polymer 3

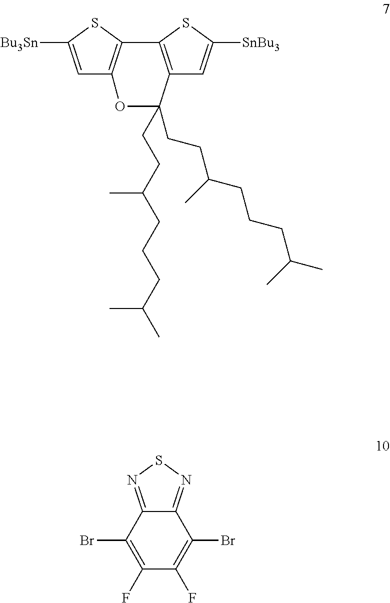

Into a 200 mL flask having an argon-purged internal atmosphere were charged 500 mg (0.475 mmol) of a compound 7, 141 mg (0.427 mmol) of a compound 10 and 32 mL of toluene, to prepare a uniform solution. The resultant toluene solution was bubbled with argon for 30 minutes. Thereafter, to the toluene solution were added 6.52 mg (0.007 mmol) of tris(dibenzylideneacetone)dipalladium and 13.0 mg of tris(2-toluoyl)phosphine, and the mixture was stirred at 100° C. for 6 hours. Thereafter, to the reaction solution was added 500 mg of phenyl bromide, and further, the mixture was stirred for 5 hours. Thereafter, the flask was cooled to 25° C., and the reaction solution was poured into 300 mL of methanol. The precipitated polymer was recovered by filtration, and the resultant polymer was placed on a Extraction Thimble, and extracted with methanol, acetone and hexane each for 5 hours using a Soxhlet extractor. The polymer remaining in the Extraction Thimble was dissolved in 100 mL of toluene, and 2 g of sodium diethyldithiocarbamate and 40 mL of water were added, and the mixture was stirred under reflux for 8 hours. The aqueous layer was removed, then, the organic layer was washed with 50 mL of water twice, then, washed with 50 mL of a 3 wt % acetic acid aqueous solution twice, then, washed with 50 mL of water twice, then, washed with 50 mL of a 5% potassium fluoride aqueous solution twice, then, washed with 50 mL of water twice, and the resultant solution was poured into methanol, to cause precipitation of a polymer. The polymer was filtrated, then, dried, and the resultant polymer was dissolved in 50 mL of o-dichlorobenzene again, and allowed to pass through an alumina/silica gel column. The resultant solution was poured into methanol, to cause precipitation of a polymer, and the polymer was filtrated, then, dried, to obtain 185 mg of a purified polymer. Hereinafter, this polymer is referred to as polymer 3.

### (Production of Composition 1)

Twenty five (25) parts by weight of [6,6]-phenylC71-butyric acid methyl ester (C70PCBM) (manufactured by American Dye Source, Inc., ADS71BFA) as a fullerene derivative, 5 parts by weight of a polymer 1 as an electron donating compound and 1000 parts by weight of o-dichlorobenzene as a solvent were mixed. Next, the mixed solution was filtrated through a Teflon (registered trademark) filter having a pore diameter of 1.0 μm, to prepare a composition 1.

### (Production of Composition 2)

Twenty five (25) parts by weight of [6,6]-phenylC71-butyric acid methyl ester (C70PCBM) (manufactured by American Dye Source, Inc., ADS71BFA) as a fullerene derivative, 2.5 parts by weight of a polymer 1 and 2.5 parts by weight of a polymer 2 as an electron donating compound, and 1000 parts by weight of o-dichlorobenzene as a solvent were mixed. Next, the mixed solution was filtrated through a Teflon (registered trademark) filter having a pore diameter of 1.0 μm, to prepare a composition 2.

### (Production of Composition 3)

Ten (10) parts by weight of [6,6]-phenylC71-butyric acid methyl ester (C70PCBM) (manufactured by American Dye Source, Inc., ADS71BFA) as a fullerene derivative, 5 parts by weight of a polymer 3 as an electron donating compound and 1000 parts by weight of o-dichlorobenzene as a solvent were mixed. Next, the mixed solution was filtrated through a Teflon (registered trademark) filter having a pore diameter of 1.0 μm, to prepare a composition 3.

### Example 1

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 1 was spin-coated to form an active layer (thickness: about 200 nm).

Next, a 40% by weight ethylene glycol monobutyl ether dispersion of zinc oxide nano particles (average particle size: 35 nm or less, maximum particle size: 120 nm or less, manufactured by Sigma Aldrich Japan K.K.) was diluted with ethylene glycol monobutyl ether in an amount of 3-fold parts by weight with respect to this dispersion, to prepare a coating solution. This coating solution was spin-coated with a thickness of 190 nm on the active layer, to form a functional layer insoluble in a water solvent. Thereafter, a neutral PEDOT:PSS dispersion of pH=6 to 7 (manufactured by H. C. Starck, Clevios PH1000N) was spin-coated with a thickness of 100 nm on the functional layer. Further, a polyaniline solution (manufactured by Nissan Chemical Industries, Ltd., ORMECON NW-F101MEK (methyl ethyl ketone solvent)) was coated, then, dried in vacuum for 60 minutes, to form a cathode composed of the PEDOT:PSS layer and the polyaniline layer laminated. The thickness of the polyaniline layer was about 700 nm. The shape of the resultant organic film solar battery was 2 mm×2 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 1.48%, the short circuit current density was 6.39 mA/cm², the open-end voltage was 0.66V and FF (fill factor) was 0.35.

### Example 2

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 2 was spin-coated to form an active layer (thickness: about 180 nm).

Next, a 45% by weight 2-propanol dispersion of zinc oxide nano particles (HTD-711Z, manufactured by TAYCA Corporation) was diluted with 2-propanol in an amount of 5-fold parts by weight with respect to this dispersion, to prepare a coating solution. This coating solution was spin-coated with a thickness of 220 nm on the active layer, to form a functional layer insoluble in a water solvent.

Thereafter, a low temperature sintering silver ink (manufactured by BANDO Chemical Industries, Ltd., Flow Metal SW-1020. A dispersion of silver nano particles in a water solvent, containing silver nano particles having a particle size of 20 to 40 nm in an amount of 40% by weight) was spin-coated with a thickness of 700 nm on the functional layer, to form a cathode. Thereafter, sealing was conducted with a UV-hardening sealant, then, heating at 120° C. was performed for 10 minutes to cause sintering of the low temperature sintering silver ink.

The shape of the resultant organic film solar battery was 4 mm×4 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 1.57%, the short circuit current density was 6.12 mA/cm², the open-end voltage was 0.76V and FF was 0.34.

### Example 3

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 2 was spin-coated to form an active layer (thickness: about 180 nm).

Next, a 45% by weight 2-propanol dispersion of zinc oxide nano particles (particle size: 20 nm to 30 nm) (HTD-711Z, manufactured by TAYCA Corporation) was diluted with 2-propanol in an amount of 5-fold parts by weight with respect to this dispersion, to prepare a coating solution. This coating solution was spin-coated with a thickness of 220 nm on the active layer, to form a functional layer insoluble in a water solvent.

Next, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted, to obtain an organic film solar battery.

The shape of the resultant organic film solar battery was 4 mm×4 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 4.77%, the short circuit current density was 8.34 mA/cm², the open-end voltage was 0.86V and FF was 0.67.

### Example 4

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 2 was spin-coated to form an active layer (thickness: about 180 nm).

Next, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted, to obtain an organic film solar battery.

The shape of the resultant organic film solar battery was 4 mm×4 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 0.7%, the short circuit current density was 5.44 mA/cm², the open-end voltage was 0.62V and FF was 0.20.

### Example 5

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 2 was spin-coated to form an active layer (thickness: about 180 nm).

Next, 1 part by weight of a 45% by weight 2-propanol dispersion of zinc oxide nano particles (particle size: 20 to 30 nm) (HTD-711Z, manufactured by TAYCA Corporation) and 5 parts by weight of 2-propanol containing sodium acetylacetonate dissolved in an amount of 1% by weight were mixed, to prepare a coating solution. This coating solution was spin-coated with a thickness of 210 nm on the active layer and dried, to form a functional layer insoluble in a water solvent.

Next, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted, to obtain an organic film solar battery.

The shape of the resultant organic film solar battery was 2 mm×2 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 5.66%, the short circuit current density was 9.89 mA/cm², the open-end voltage was 0.90V and FF was 0.64.

### Example 6

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 2 was spin-coated to form an active layer (thickness: about 180 nm).

Next, 1 part by weight of a 45% by weight 2-propanol dispersion of zinc oxide nano particles (particle size: 20 to 30 nm) (HTD-711Z, manufactured by TAYCA Corporation) and 5 parts by weight of 2-propanol containing cesium acetate dissolved in an amount of 1% by weight were mixed, to prepare a coating solution. This coating solution was spin-coated with a thickness of 210 nm on the active layer and dried, to form a functional layer insoluble in a water solvent.

Next, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted, to obtain an organic film solar battery.

The shape of the resultant organic film solar battery was 2 mm×2 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 5.69%, the short circuit current density was 10.41 mA/cm², the open-end voltage was 0.89V and FF was 0.62.

### Example 7

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 2 was spin-coated to form an active layer (thickness: about 180 nm).

Next, 1 part by weight of a 45% by weight 2-propanol dispersion of zinc oxide nano particles (particle size: 20 to 30 nm) (HTD-711Z, manufactured by TAYCA Corporation) and 5 parts by weight of 2-propanol containing cesium acetate dissolved in an amount of 5% by weight were mixed, to prepare a coating solution. This coating solution was spin-coated with a thickness of 210 nm on the active layer and dried, to form a functional layer insoluble in a water solvent.

Next, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted, to obtain an organic film solar battery.

The shape of the resultant organic film solar battery was 2 mm×2 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 5.64%, the short circuit current density was 9.63 mA/cm², the open-end voltage was 0.89V and FF was 0.66.

### Example 8

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 3 was spin-coated to form an active layer (thickness: about 100 nm).

Next, a 45% by weight 2-propanol dispersion of zinc oxide nano particles (HTD-711Z, manufactured by TAYCA Corporation) was diluted with 2-propanol in an amount of 5-fold parts by weight with respect to this dispersion, to prepare a coating solution. This coating solution was spin-coated with a thickness of 220 nm on the active layer, to form a functional layer insoluble in a water solvent.

Next, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted, to obtain an organic film solar battery.

The shape of the resultant organic film solar battery was 2 mm×2 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 2.84%, the short circuit current density was 7.91 mA/cm², the open-end voltage was 0.67V and FF was 0.54.

### Example 9

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 3 was spin-coated to form an active layer (thickness: about 100 nm).

Next, 1 part by weight of a 45% by weight 2-propanol dispersion of zinc oxide nano particles (particle size: 20 to 30 nm) (HTD-711Z, manufactured by TAYCA Corporation) and parts by weight of 2-propanol containing sodium acetylacetonate dissolved in an amount of 1% by weight were mixed, to prepare a coating solution. This coating solution was spin-coated with a thickness of 210 nm on the active layer and dried, to form a functional layer insoluble in a water solvent.

Next, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted, to obtain an organic film solar battery.

The shape of the resultant organic film solar battery was 2 mm×2 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 3.20%, the short circuit current density was 8.40 mA/cm², the open-end voltage was 0.67V and FF was 0.57.

### (Production of Composition 4)

Then (10) parts by weight of [6,6]-phenylC61-butyric acid methyl ester (C60PCBM) (manufactured by Frontier Carbon Corporation, E 100) as a fullerene derivative, 5 parts by weight of a polymer 3 as an electron donating compound and, 1000 parts by weight of o-dichlorobenzene as a solvent were mixed. Next, the mixed solution was filtrated through a Teflon (registered trademark) filter having a pore diameter of 1.0 μm, to prepare a composition 4.

### Example 10

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 2 was spin-coated to form an active layer 1 (thickness: about 190 nm).

Next, a 45% by weight 2-propanol dispersion of zinc oxide nano particles (particle size: 20 nm to 30 nm) (HTD-711Z, manufactured by TAYCA Corporation) was diluted with 2-propanol in an amount of 5-fold parts by weight with respect to this dispersion, to prepare a coating solution. This coating solution was spin-coated with a thickness of 220 nm on the active layer, to form a functional layer insoluble in a water solvent.

Thereafter, a neutral PEDOT:PSS dispersion of pH=6 to 7 (manufactured by H. C. Starck, Clevios PH1000N) was further diluted with 1-fold part by weight of ultrapure water to give a coating solution which was then spin-coated with a thickness of 30 nm on an electron transporting layer, to obtain a hole transporting layer.

Thereafter, the above-described coating solution 4 was spin-coated with a thickness of 110 nm on a hole transporting layer, to obtain an active layer 2 of an organic film solar battery.

Next, a 45% by weight 2-propanol dispersion of zinc oxide nano particles (particle size: 20 nm to 30 nm) (HTD-711Z, manufactured by TAYCA Corporation) was diluted with 2-propanol in an amount of 5-fold parts by weight with respect to this dispersion, to prepare a coating solution. This coating solution was spin-coated with a thickness of 220 nm on the active layer, to form a functional layer insoluble in a water solvent.

Next, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted to obtain a serial tandem type organic film solar battery.

The shape of the resultant organic film solar battery was 2 mm×2 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 5.77%, the short circuit current density was 7.78 mA/cm², the open-end voltage was 1.36V and FF was 0.55.

### Example 11

### Fabrication and Evaluation of Organic Film Solar Battery

A glass substrate carrying an ITO film formed thereon functioning as an anode of a solar battery was prepared. The ITO film was one formed by a sputtering method, and its thickness was 150 nm. This glass substrate was treated with ozone and UV, thereby treating the surface of the ITO film. Next, a PEDOT:PSS solution (manufactured by H. C. Starck, CleviosP VP AI4083) was spin-coated on the ITO film, and heated at 120° C. in atmospheric air for 10 minutes to form a hole injection layer having a thickness of 50 nm. On this hole injection layer, the above-described composition 2 was spin-coated to form an active layer (thickness: about 230 nm).

Next, a 20% by weight methyl ethyl ketone dispersion of gallium zinc oxide nano particles (particle size: 20 nm to 40 nm) (Pazet GK, manufactured by Hakusui Teck Co., Ltd.) was spin-coated with a thickness of 220 nm on the active layer, to form a functional layer insoluble in a water solvent.

Further, a dispersion of a wire-shape electric conductor in a water solvent (ClearOhm (registered trademark) Ink-N AQ: manufactured by Cambrios Technologies Corporation) was coated by a spin coater and dried, to obtain a cathode composed of an electrically conductive wire layer having a thickness of 120 nm. Thereafter, sealing with a UV-hardening sealant was conducted to obtain a serial tandem type organic film solar battery.

The shape of the resultant organic film solar battery was 1.8 mm×1.8 mm regular tetragon. Using a solar simulator (manufactured by BUNKOUKEIKI Co., Ltd., trade name: OTENTO-SUNII: AM 1.5G filter, irradiance: 100 mW/cm²), the resultant organic film solar battery was irradiated with constant light and the photoelectric conversion efficiency was measured by measuring the generating current and voltage. The photoelectric conversion efficiency was 5.43%, the short circuit current density was 9.76 mA/cm², the open-end voltage was 0.80V and FF (fill factor) was 0.69.

### INDUSTRIAL APPLICABILITY

The present invention is useful since it provides a novel method of producing an organic photoelectric conversion device.

1. A method of producing an organic photoelectric conversion device, comprising forming an anode, forming an active layer on the anode, then, forming a cathode on the active layer by a coating method.

2. The method according to claim 1, wherein after formation of the active layer and before formation of the cathode, a coating solution containing an electron transporting material is coated on the active layer to form a functional layer.

3. The method according to claim 2, wherein the electron transporting material is granulous zinc oxide.

4. The method according to claim 2, wherein the coating solution containing the electron transporting material contains at least one selected from the group consisting of complexes of alkali metals, salts of alkali metals, complexes of alkaline earth metals and salts of alkaline earth metals.

5. The method according to claim 2, wherein the electron transporting material is granulous zinc oxide and the coating solution containing the electron transporting material contains at least one selected from the group consisting of complexes of alkali metals, salts of alkali metals, hydroxides of alkali metals, complexes of alkaline earth metals, salts of alkaline earth metals and hydroxides of alkaline earth metals.

6. The method according to claim 1, wherein formation of the active layer is carried out by a coating method.

7. The method according to claim 1, wherein the cathode contains polythiophene and/or polythiophene derivative.

8. The method according to claim 1, wherein the cathode contains polyaniline and/or polyaniline derivative.

9. The method according to claim 1, wherein the cathode contains nano particles of an electrically conductive substance, nano wires of an electrically conductive substance or nano tubes of an electrically conductive substance.

10. The method according to claim 1, wherein the active layer contains fullerenes and/or derivatives of fullerenes, and a conjugated high molecular weight compound.

11. An organic photoelectric conversion device having a constitution in which an anode, an active layer and a cathode are laminated in this order on a supporting substrate wherein the cathode is formed by a coating method.

12. An organic photoelectric conversion device having a constitution in which an anode, an active layer, a functional layer and a cathode are laminated in this order on a supporting substrate wherein the cathode is formed by a coating method and the functional layer is formed by coating a coating solution containing granulous zinc oxide, containing at least one selected from the group consisting of complexes of alkali metals, salts of alkali metals, hydroxides of alkali metals, complexes of alkaline earth metals, salts of alkaline earth metals and hydroxides of alkaline earth metals, on the active layer.
